(19) United States
(12) Patent Application Publication
(10) Pub. No.: US 2018/0039304 A1
(43) Pub. Date: Feb. 8, 2018

(54) GLASS HOUSING AND ELECTRONIC DEVICE HAVING THE SAME

(71) Applicants: SHENZHEN O-FILM TECH. CO., LTD., Shenzhen (CN); NANCHANG O-FILM OPTICAL TECHNOLOGY CO., LTD., Nanchang (CN)

(72) Inventors: Wei LIU, Nanchang (CN); Genchu TANG, Nanchang (CN); Bin TANG, Nanchang (CN)

(73) Assignees: SHENZHEN O-FILM TECH. CO., LTD., Shenzhen (CN); NANCHANG O-FILM OPTICAL TECHNOLOGY CO., LTD., Nanchang (CN)

(21) Appl. No.: 15/452,722

(22) Filed: Mar. 7, 2017

(30) Foreign Application Priority Data
Aug. 3, 2016 (CN) 201610628896.7

(51) Int. Cl. G06F 1/16; H05K 5/02

(52) U.S. Cl. CPC G06F 1/1656; H05K 5/0243

(57) ABSTRACT

A glass housing includes: an inner surface; an outer surface opposite to the inner surface; and a circumferential surface interconnecting the outer surface and the inner surface, wherein the inner surface is a concave spherical surface, and the outer surface is a convex spherical surface, a distance between the inner surface and the outer surface ranges from 0.2 mm to 0.8 mm, in a cross-section of the glass housing on which geometric centers and spherical centers of the inner surface and the outer surface are located, an arc length L of the outer surface is less than or equal to 80 mm, an angle C formed by connection lines between opposite ends of the arc and the spherical center satisfies 30°<C<180°.

This application claims priority under 35 U.S.C. §119 to Chinese Patent Application Nos. 201610628896.7, filed on Aug. 3, 2016. The entire teachings of the above application are incorporated herein by reference.

### FIELD OF THE INVENTION

The present disclosure relates to electronic devices, and more particularly, relates to a glass housing and an electronic device having the glass housing.

### BACKGROUND OF THE INVENTION

With the development of electronic devices such as smart phone and smart watch, which are provided with a touch screen, various manufacturers scramble to launch differentiated devices, hoping to attract the consumers. A highlight design emerging in the current market is that, the housing of the electronic device is configured to be a curved housing. The electronic device having a curved housing can fit the hand of the user better, providing a comfortable sensation for holding and handling the electronic device. If the watch housing is configured to be a curved housing, it can fit the wrist of the user better, thereby providing a comfortable sensation for wearing the watch. Furthermore, when a display housing having the curved configuration, the displaying content displayed on the display can have an intense stereoscopic impression, and a perception can thereby be improved. Because glass has a better tactile sensation, when it serves as the materials of the housing of the electronic device, the electronic device meets a great favor. However, when the glass housing of the electronic device is configured to be a convex curved housing, it cracks easily when falls by an accident.

### SUMMARY

Accordingly, it is necessary to provide a glass housing having a dispersed stress and a high strength, and an electronic device having the glass housing.

A glass housing includes: an inner surface; an outer surface opposite to the inner surface; and a circumferential surface interconnecting the outer surface and the inner surface, wherein the inner surface is a concave spherical surface, and the outer surface is a convex spherical surface, a distance between the inner surface and the outer surface ranges from 0.2 mm to 0.8 mm, in a cross-section of the glass housing on which geometric centers and spherical centers of the inner surface and the outer surface are located, an arc length L of the outer surface is less than or equal to 80 mm, an angle C formed by connection lines between opposite ends of the arc and the spherical center satisfies 30°<C<180°.

An electronic device includes aforementioned glass housing.

By aforementioned configuration of the structural parameters, the concentrated stress applied to the glass housing is dispersed, an integral strength of the glass housing is enhanced. The risk that cracks emerge easily by a slight collision due to the concentrated stress is reduced.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is a perspective view of a glass housing according to an embodiment;

FIG. 2 is a front view of the glass housing of FIG. 1;

FIG. 3 is a cross-sectional view taken along line A-A of FIG. 2; and

FIG. 4 is an end view of an electronic device having a glass housing.

### DETAILED DESCRIPTION OF THE EMBODIMENTS

Embodiments of the invention are described more fully hereinafter with reference to the accompanying drawings, in which preferred embodiments of the invention are shown. The various embodiments of the invention may, however, be embodied in many different forms and should not be construed as limited to the embodiments set forth herein. Rather, these embodiments are provided so that this disclosure will be thorough and complete, and will fully convey the scope of the invention to those skilled in the art.

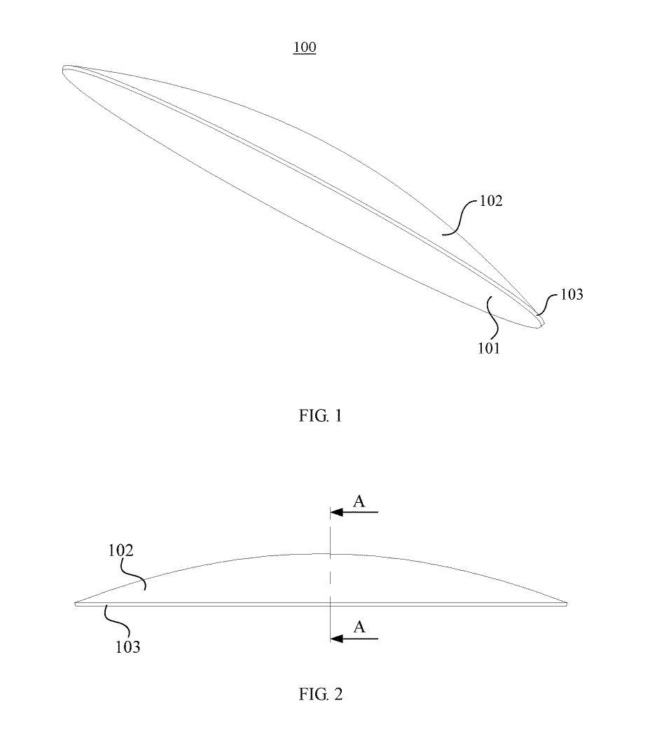

As shown in FIG. 1, a glass housing 100 is provided according to one embodiment, which can be applied to electronic devices such as a smart phone or a smart watch. The glass housing can serve as a display housing of the phone or the watch, or it can also serve as a back cover plate of the phone or the watch.

The glass housing includes an inner surface 101, an outer surface 102 opposite to the inner surface 101, and a circumferential surface 103 interconnecting the outer surface 102 and the inner surface 101. The inner surface 101 is a concave spherical surface, and the outer surface 102 is a convex spherical surface. When the glass housing is applied to the electronic device, the inner surface 101 can serve as an outer surface of the back cover plate of the electronic device, the inner surface 101 can also serve as an outer surface of a display panel of the electronic device, or the inner surface 101 can also serve as an inner surface of the display panel of electronic device (i.e. the outer surface 102 faces the user). In an alternative embodiment, the glass serves as a displaying housing of the electronic device, the outer surface 102 faces the user. A distance between the inner surface 101 and the outer surface 102, i.e. a thickness of the glass housing ranges from 0.2 mm to 0.8 mm.

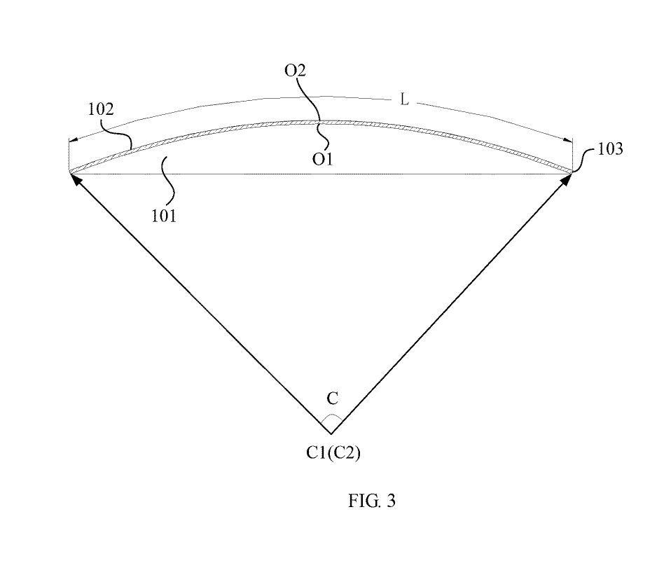

Also referring to FIG. 2 and FIG. 3, the inner surface 101 has a geometric center O1, and the outer surface 102 has a geometric center O2. The inner surface 101 has a corresponding spherical center C1, and the outer surface 102 has a corresponding spherical center C2. FIG. 3 is a cross-section of the glass housing on which the geometric center O1 and the spherical center C1 of the inner surface 101, and the geometric center O2 and the spherical center C2 of the outer surface 102 are located. In the illustrated embodiment, the spherical center C1 and the spherical center C2 are overlapped. The geometric center O1, the geometric center O2, and the spherical center C1 are collinear, thus the geometric center O2 and the spherical center C2 are also located on the cross-section.

In the cross-section, the outer surface 102 has an arc length L, L≦80 mm. The outer surface 102 has an arc with a length less than L. An angle C formed by connection lines between opposite ends of the arc and the spherical center satisfies 30°<C<180°. In an alternative embodiment, 60°<C<180°.

By aforementioned configuration of the structural parameters, the concentrated stress applied to the glass housing is dispersed, an integral strength of the glass housing is enhanced. The risk that cracks emerge easily by a slight collision due to the concentrated stress is reduced.

In an alternative embodiment, the inner surface 101 and outer surface 102 each has a radius R,R>10 mm, and in the illustrated embodiment,R>50 mm. The radius of the inner surface 101 and the radius of the outer surface 102 can be same, or can also be different. When the radius of the inner surface 101 is equal to the radius of the outer surface 102, the spherical center C1 of the inner surface 101 and the spherical center C2 of the outer surface 102 are not overlapped.

In an alternative embodiment, distances between each portion of the inner surface 101 and the outer surface 102 are the same, i.e. the glass housing has a uniform thickness, such that the stress concentration can be eliminated, and the integral strength of the glass housing can be improved.

The geometric center O1 of the inner surface 101, the geometric center O2 of the outer surface 102, the spherical center C1, and the spherical center C2 are collinear, thus the glass housing has a regular conformation. As shown in FIG. 3, the glass housing is a rotational symmetry body, a rotation axis of the glass housing is a connecting line connecting the geometric center O1, the geometric center O2, the spherical center C1, and the spherical center C2.

In the illustrated embodiment, outer profiles of the inner surface 101 and the outer surface 102 are spherical surfaces. It should be understood that, in alternative embodiment, the outer profile can be in other shapes such as an elliptical surface or an oblong surface, and so on. The circumferential surface 103 can be a cylindrical surface. In the embodiment as shown in FIG. 1 through FIG. 3, the circumferential surface 103 is a side surface of a truncated cone. A climax of the truncated cone, the spherical center C1 of the inner surface 101, and the spherical center C2 of the outer surface 102 are located at a same side of the glass housing.

In the manufacturing process of the glass housing, a hardening treatment may be performed to one of the inner surface 101 and the outer surface 102, such that the inner surface 101 and/or the outer surface 102 has a compressive stress layer. Usually, in the machining process of the glass, edges of the glass surface will generate micro-cracks inevitably. The micro-cracks can radically decrease the strength of the glass. A size of the micro-crack may be decreased by physical machining processes such as polishing, but a further chemical hardening treatment may obtain a better effect. For example, under a predetermined temperature, the glass may be immersed into a fused salt, the alkali metal ions in the glass may be exchanged with the alkali metal ions in the fused salt, thereby a compressive stress layer having a predetermined thickness is formed on the surface of the glass, thus the compressive stress layer is not an stratified structure additionally attached to the surface, but a strengthening layer formed from the surface of the glass inwardly within a predetermined thickness. The compressive stress layer causes the cracks not to be expanded, and thereby improving the strength of the glass.

In an alternative embodiment, after a first hardening treatment, the obtained compressive stress layer has a thickness of 50 μm to 100 μm, the compressive stress layer has a compressive stress of 200 Mpa to 300 Mpa. A central tensional stress between the inner surface and the outer surface is less than or equal to 100 Mpa.

In an alternative embodiment, after a second hardening treatment, the obtained compressive stress layer has a thickness of 60 μm to 69 μm, i.e. in the second hardening treatment, the depth of the ion exchange is less than the depth of the ion exchange in the first hardening treatment. The compressive stress layer has a compressive stress of 710 Mpa to 850 Mpa. The central tensional stress between the inner surface and the outer surface is less than or equal to 160 Mpa. By multiple hardening treatments, the compressive stress value of the surface can be enhanced, and the strength of the glass is thereby improved. However, the central tensional stress is increased accompanying to an improvement of the compressive stress of the surface, if the central tensional stress is excessively increased, the glass may crack from an inner side toward an outer side, and causes a spontaneous explosion. Therefore, the central tensional stress should be controlled, that is, the compressive stress cannot be increased without limit.

In an alternative embodiment, at least one of the inner surface 101 and the outer surface 102 is attached by an antireflection layer. The antireflection layer can be formed by evaporation or sputtering.

In an alternative embodiment, an anti-fingerprint layer is formed on and attached to the outer surface 102. The anti-fingerprint layer has an initial water droplet contact angle, the initial water droplet contact angle is greater than or equal to 110°. The so-called water droplet contact angle is an angle defined by the gas-liquid phase interface and the solid-liquid phase interface, which are located at the solid-liquid-gas three phases interfaces. The water droplet contact angle is greater, the anti-fingerprint layer has a better hydrophobicity and a better anti-fouling performance. The initial water droplet contact angle is detected under the conditions that the formed anti-fingerprint layer is not used and not destroyed. The water droplet contact angle will decrease accompanying to a prolonging of the forming time and an increase of the wearing degree of the anti-fingerprint layer.

In an alternative embodiment, at least one decorative layer is contained in the inner surface 101. The decorative layer can be formed by ink printing or pasting a decorative film.

When the decorative layer is formed by ink printing, the decorative layer has a thickness of 5 μm to 40 μm. When the decorative layer is formed by pasting a decorative film, the decorative film has a thickness of 10 μm to 125 μm. The decorative layer may be formed by silk-screening an explosion-proof membrane, and can also be formed by silk-screening a glue layer directly without a substrate.

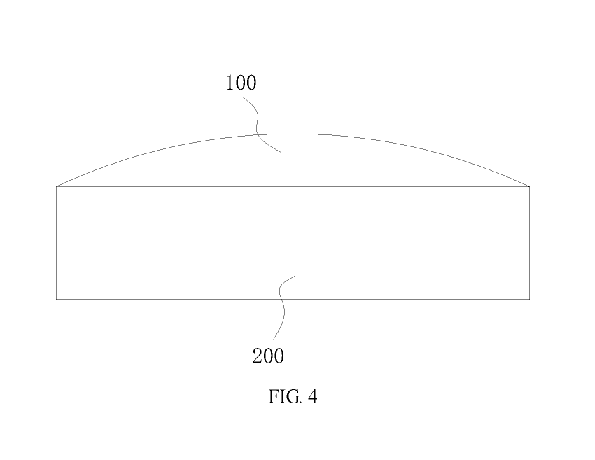

The present disclosure further provides an electronic device having aforementioned glass housing. The electronic device can be a smart phone, a smart watch, and so on. Referring to FIG. 4, in an embodiment, for example, the electronic device includes a communicating main body 200 and a glass housing 100 assembled to the communicating main body 200.

Technical features of above embodiments can be combined arbitrary, for simple, any combination of every technical feature in above embodiments is not all illustrated. However, the technical features which are not contradicted to each other may fall into the scope of the specification.

The above are several embodiments of the present invention described in detail, and should not be deemed as limitations to the scope of the present invention. It should be noted that variations and improvements will become apparent to those skilled in the art to which the present invention pertains without departing from its spirit and scope. Therefore, the scope of the present invention is defined by the appended claims.

What is claimed is:

1. A glass housing, comprising:
an inner surface;
an outer surface opposite to the inner surface; and
a circumferential surface interconnecting the outer surface and the inner surface, wherein the inner surface is a concave spherical surface, and the outer surface is a convex spherical surface, a distance between the inner surface and the outer surface ranges from 0.2 mm to 0.8 mm, in a cross-section of the glass housing on which geometric centers and spherical centers of the inner surface and the outer surface are located, a length L of an arc of the outer surface is less than or equal to 80 mm, an angle C formed by connection lines between opposite ends of the arc and the spherical center satisfies 30°<C<180°.

2. The glass housing according to claim 1, wherein the inner surface and the outer surface each has a radius R, R>10 mm.

3. The glass housing according to claim 1, wherein distances between each portion of the inner surface and the outer surface are the same.

4. The glass housing according to claim 1, wherein the circumferential surface is a cylindrical surface.

5. The glass housing according to claim 1, wherein the circumferential surface is a side surface of a truncated cone, wherein a climax of the truncated cone, the spherical center of the inner surface, and the spherical center of the outer surface are located at a same side of the glass housing.

6. The glass housing according to claim 1, wherein the geometric centers and the spherical centers of the inner surface and the outer surface are collinear.

7. The glass housing according to claim 1, wherein at least one of the inner surface and the outer surface is provided with a compressive stress layer, the compressive stress layer has a thickness of 50 μm to 100 μm, the compressive stress layer has a compressive stress of 200 Mpa to 300 Mpa, a central tensional stress between the inner surface and the outer surface is less than or equal to 100 Mpa.

8. The glass housing according to claim 1, wherein at least one of the inner surface and the outer surface is provided with a compressive stress layer, the compressive stress layer has a thickness of 60 μm to 69 μm, the compressive stress layer has a compressive stress of 710 Mpa to 850 Mpa, a central tensional stress between the inner surface and the outer surface is less than or equal to 160 Mpa.

9. The glass housing according to claim 1, wherein at least one of the inner surface and the outer surface is attached by an antireflection layer.

10. The glass housing according to claim 1, wherein the outer surface is attached by an anti-fingerprint layer, the anti-fingerprint layer has an initial water droplet contact angle greater than or equal to 110°.

11. The glass housing according to claim 1, wherein the inner surface is provided with a decorative layer formed by ink printing, the decorative layer has a thickness of 5 μm to 40 μm.

12. The glass housing according to claim 1, wherein the inner surface is provided with a decorative layer, the decorative layer is formed by attaching a decorative film, the decorative film has a thickness of 10 μm to 125 μm.

13. An electronic device, comprising a glass housing, wherein the glass housing comprises:
an inner surface;
an outer surface opposite to the inner surface; and
a circumferential surface interconnecting the outer surface and the inner surface, wherein the inner surface is a concave spherical surface, and the outer surface is a convex spherical surface, a distance between the inner surface and the outer surface ranges from 0.2 mm to 0.8 mm, in a cross-section of the glass housing on which geometric centers and spherical centers of the inner surface and the outer surface are located, an arc length L of the outer surface is less than or equal to 80 mm, an angle C formed by connection lines between opposite ends of the arc and the spherical center satisfies 30°<C<180°.
